(19) United States
(12) Patent Application Publication
(10) Pub. No.: US 2020/0136468 A1
(43) Pub. Date: Apr. 30, 2020

(54) ELECTRIC MOTOR WITH INTEGRATED MOTOR CONTROLLER

(71) Applicant: STOLLMEYER TECHNOLOGIES, LLC, San Luis Obispo, CA (US)

(72) Inventors: MARCUS RICHARD STOLLMEYER, SANTA MARIA, CA (US); JOSEPH RILEY COPLON, SAN LUIS OBISPO, CA (US)

(21) Appl. No.: 16/177,298

(22) Filed: Oct. 31, 2018

(51) Int. Cl. H02K 9/08; B64C 39/02; H05K 1/18; H02K 11/33; H02K 15/14; H05K 1/02; H02K 11/00

(52) U.S. Cl. CPC H02K 9/08; B64C 39/024; H05K 1/183; H02K 11/33; H05K 2201/1009; H05K 1/021; H02K 11/0094; B64C 2201/042; H02K 15/14

(57) ABSTRACT

A motor unit system is described. The motor unit system may include a housing with a brushless direct current motor and a motor controller contained within the same housing, where the motor controller comprises a printed circuit board, and an integrated circuit mounted on a component side of the printed circuit board, and a base plate at one end of the housing. The integrated circuit may be interposed between the base plate and the printed circuit board.

This application relates to the following applications filed concurrently herewith. The related applications, all of which are incorporated herein by reference, are:

Attorney Docket No. 20966-143349-US, U.S. patent application Ser. No. ______, of Stollmeyer, et al., entitled ELECTRIC MOTOR WITH NAVIGATIONAL LIGHT;

Attorney Docket No. 20966-143350-US, U.S. patent application Ser. No. ______, of Stollmeyer, et al., entitled ELECTRIC MOTOR WITH AN INTEGRAL MOTOR CONTROLLER; and

Attorney Docket No. 20966-143352-US, U.S. patent application Ser. No. ______, of Stollmeyer, et al., entitled ELECTRIC MOTOR WITH SENSORS.

### BACKGROUND OF THE INVENTION

### 1. Field of the Invention

The present invention relates generally to an electric motor, and more specifically to an electric motor integrated with a motor controller.

### 2. Discussion of the Related Art

Various systems and processes are known in the art for an electric motor controlled by a motor controller. However, in some cases, the motor controller is provided separately from the electric motor to prevent heat from the motor from damaging the motor controller. However, this may result in an inefficient and unintegrated design.

### SUMMARY

A motor unit system is described. The motor unit system may include a housing comprising a circular cross-section and further comprising a plurality of mounting holes on one end of the housing, a brushless direct current motor comprising a shaft and a winding, the shaft extending from inside the housing to outside of the housing through a hole at the one end of the housing or another end of the housing, the other end of the housing being opposite the one end of the housing, the winding being contained within the housing, a motor controller contained within the housing, wherein the motor controller comprises a printed circuit board, and an integrated circuit mounted on the printed circuit board on a component side of the printed circuit board, and a base plate at the one end of the housing having a first side and a second side, wherein the first side comprises the plurality of mounting holes on the one end of the housing, and wherein the integrated circuit is interposed between the second side and the component side.

An unmanned vehicle is described. The unmanned vehicle may include a frame, one or more propulsion units, and a motor unit system; the motor unit system including a housing comprising a circular cross-section and further comprising a plurality of mounting holes on one end of the housing, a brushless direct current motor comprising a shaft and a winding, the shaft extending from inside the housing to outside of the housing through a hole at the one end of the housing or another end of the housing, the other end of the housing being opposite the one end of the housing, the winding being contained within the housing, a motor controller contained within the housing, wherein the motor controller comprises a printed circuit board, and an integrated circuit mounted on the printed circuit board on a component side of the printed circuit board, and a base plate at the one end of the housing having a first side and a second side, wherein the first side comprises the plurality of mounting holes on the one end of the housing, and wherein the integrated circuit is interposed between the second side and the component side.

A method of manufacturing a motor unit system is described. The method may include providing a housing comprising a circular cross-section and further comprising a plurality of mounting holes on one end of the housing, providing a brushless direct current motor comprising a shaft and a winding, the shaft extending from inside the housing to outside of the housing through a hole at the one end of the housing or another end of the housing, the other end of the housing being opposite the one end of the housing, the winding being contained within the housing, providing a motor controller contained within the housing, wherein the motor controller comprises a printed circuit board, and an integrated circuit mounted on the printed circuit board on a component side of the printed circuit board, and providing a base plate at the one end of the housing having a first side and a second side, wherein the first side comprises the plurality of mounting holes on the one end of the housing, and wherein the integrated circuit is interposed between the second side and the component side.

Some examples of the motor unit system, unmanned vehicle, and method described above may further include a thermal interface material interposed between the base plate and the integrated circuit. In some examples of the motor unit system, unmanned vehicle, and method described above, said printed circuit board comprises another integrated circuit mounted on the printed circuit board on the component side of the printed circuit board.

Some examples of the motor unit system, unmanned vehicle, and method described above may further include a capacitor mounted on the printed circuit board on a backside of the printed circuit board, the backside being opposite the component side. Some examples of the motor unit system, unmanned vehicle, and method described above may further include a second capacitor mounted on the printed circuit board on the backside of the printed circuit board.

In some examples of the motor unit system, unmanned vehicle, and method described above, said housing comprises a first opening in which the capacitor is positioned, and a second opening in which the other capacitor is positioned. In some examples of the motor unit system, unmanned vehicle, and method described above, the motor is thermally coupled to the housing and the integrated circuit is thermally coupled to the base plate.

### BRIEF DESCRIPTION OF THE DRAWINGS

FIG. 1 shows an example of a perspective view of a motor unit system of an unmanned vehicle in accordance with aspects of the present disclosure.

FIG. 2 shows an example of a front view of a motor unit system in accordance with aspects of the present disclosure.

FIG. 3 shows an example of a side view of a motor unit system in accordance with aspects of the present disclosure.

FIG. 4 shows an example of an exploded view of a motor unit system in accordance with aspects of the present disclosure.

FIG. 5 shows an example of a motor controller in accordance with aspects of the present disclosure.

FIG. 6 shows an example of a base plate in accordance with aspects of the present disclosure.

FIG. 7 shows an example of a motor controller mounted to a base plate in accordance with aspects of the present disclosure.

FIG. 8 shows an example of a schematic of a motor unit system in accordance with aspects of the present disclosure.

FIG. 9 shows an example of a process for manufacturing a motor unit system in accordance with aspects of the present disclosure.

### DETAILED DESCRIPTION

The present disclosure describes a configuration of a motor unit system with an integrated motor controller in which air may be drawn over the motor controller before passing over the motor. This may enable the air to cool the motor controller before the motor, thereby preventing heat from the motor from being transferred to the motor controller.

The following description is not to be taken in a limiting sense, but is made merely for the purpose of describing the general principles of exemplary embodiments. The scope of the invention should be determined with reference to the claims.

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the following description, numerous specific details are provided to provide a thorough understanding of embodiments of the invention. One skilled in the relevant art will recognize, however, that the invention can be practiced without one or more of the specific details, or with other methods, components, materials, and so forth. In other instances, well-known structures, materials, or operations are not shown or described in detail to avoid obscuring aspects of the invention.

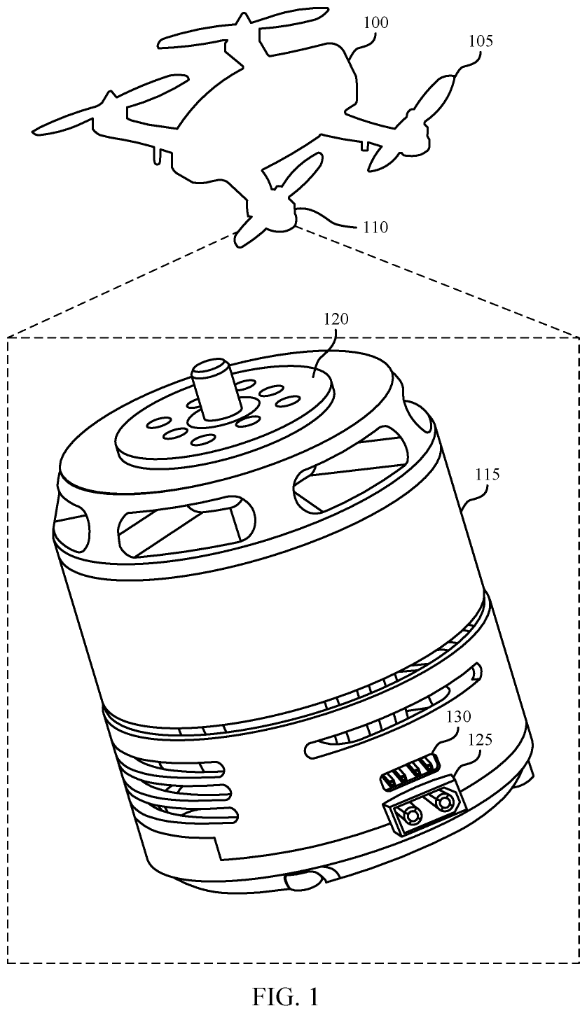

FIG. 1 shows an example of a perspective view of a motor unit system 110 of an unmanned vehicle 100 in accordance with aspects of the present disclosure. Unmanned vehicle 100 may include propulsion unit 105 and motor unit system 110.

In some embodiments, the motor unit system 110 may be combined with other components to produce an unmanned aerial vehicle (UAV). By combining a motor 120 with a light source and a motor controller with an electronic speed control (ESC), the motor unit system 110 may enable faster and easier assembly as well as more robust performance. Some embodiments may be used in conjunction with a connector system that enables quick assembly without soldering. In some cases, the motor unit system 110 may also include a built-in direction switch and nav light switch.

Based on the configuration of the motor controller, air may be drawn over a printed circuit board first, and then over the motor, so as to cool the motor controller first, and the motor second with the air, thereby preventing the heat transferred from the motor to the air from being subsequently transferred to the motor controller.

The motor unit system 110 may be configured with elements that enable durable and reliable performance in a variety of flight conditions. For example, an internal ESC may be conformally coated to protect the motor unit system 110 from damage in wet conditions.

In one embodiment, the motor 120 may operate at 3,515 revolutions per minute (RPM) and 500 kV. An example shaft size may be 4 mm, and an example weight for the motor unit system 110 may be from 150-200 g. The input voltage range may be between 10V-25.5V.

In some examples, the motor unit system 110 may be used in conjunction with a battery power source. For example, the battery may be a 4 cell to 6 cell Lithium polymer (LiPo) battery with 14.8v-22.2v Continuous Current, and 20 Amps (500 W), with a burst current of 35 Amps. However, one skilled in the art will recognize that other battery systems may be suitable for powering the motor unit system 110.

In some examples, the motor unit system 110 may be connected to a frame of a UAV, and may power a propulsion unit 105 such as a propeller. For example, the propulsion unit 105 for a multi-rotor vehicle may have a 12-inch to 15-inch Diameter, with a 3-inch to 5-inch pitch. For a fixed wing vehicle, the propulsion unit 105 may have a 9-inch to 13-inch Diameter, with a 5-inch to 9-inch pitch. In one embodiment, the total vehicle weight for a multi-rotor vehicle may be up to 1.5 KG per motor 120. In some fixed wing embodiments, the total weight may be up to 4 KG per motor 120.

The motor 120 may be powerful enough to lift wide array of vehicles and payloads, and may be durable and reliable enough to perform in a wide variety of conditions. In some examples, the ESC may be pre-tuned for precision and efficiency, and may be conformally coated to increased reliability. The light source may enable line-of-sight flying, and may greatly improve visibility and safety. By combining the light source with the motor 120 unit, the vehicle may achieve a desirable form factor. In some examples, a switch on the back of the motor unit system 110 may allow a user to dictate the direction of the rotor rotation.

The motor unit system 110 may be configured with one or more solder-free connection points, so that the motor unit system 110 may be simply plugged into a vehicle. In some examples, the motor unit system 110 may include, or may be packaged with a pre-soldered cable and a connector system to connect the motor unit system 110 to a power input 125, a throttle input, and a propulsion unit 105.

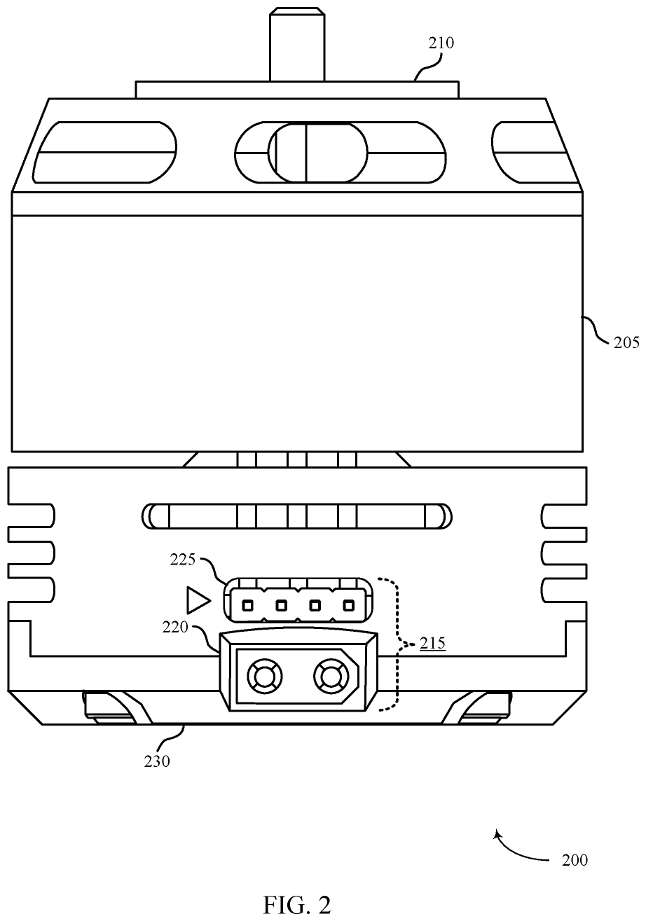

Motor unit system 110 may be an example of, or include aspects of, the corresponding elements described with reference to FIGS. 2-4, and 8. Motor unit system 110 may include housing 115, motor 120, power input 125, data input 130, and base plate 135.

Housing 115 may have a circular cross-section and may include a plurality of mounting holes on one end of the housing 115. In some examples, said housing 115 includes a first opening in which a capacitor is positioned, and a second opening in which another capacitor is positioned. In other examples, the housing includes space for more than two capacitors. Housing 115 may be an example of, or include aspects of, the corresponding elements described with reference to FIGS. 2-4.

Motor 120 may include a shaft and a winding, the shaft extending from inside the housing 115 to outside of the housing 115 through a hole at the one end of the housing 115 or another end of the housing 115, the other end of the housing 115 being opposite the one end of the housing 115, the winding being contained within the housing 115. In some examples, the motor 120 is thermally coupled to the housing 115 and the integrated circuit is thermally coupled to the base plate 135. Motor 120 may be an example of, or include aspects of, the corresponding elements described with reference to FIGS. 2-4, and 8.

Power input 125 and data input 130 may be examples of, or include aspects of, the corresponding elements described with reference to FIGS. 2-5, and 8.

Base plate 135 may be located at the one end of the housing 115 having a first side and a second side, where the first side includes the plurality of mounting holes on the one end of the housing 115, and where the integrated circuit is interposed between the second side and the component side. Base plate 135 may be an example of, or include aspects of, the corresponding elements described with reference to FIGS. 2-4, 6, and 7.

FIG. 2 shows an example of a front view of a motor unit system 200 in accordance with aspects of the present disclosure. Motor unit system 200 may be an example of, or include aspects of, the corresponding elements described with reference to FIGS. 1, 3, 4, and 8. Motor unit system 200 may include housing 205, motor 210, opening 215, power input 220, data input 225, and base plate 230.

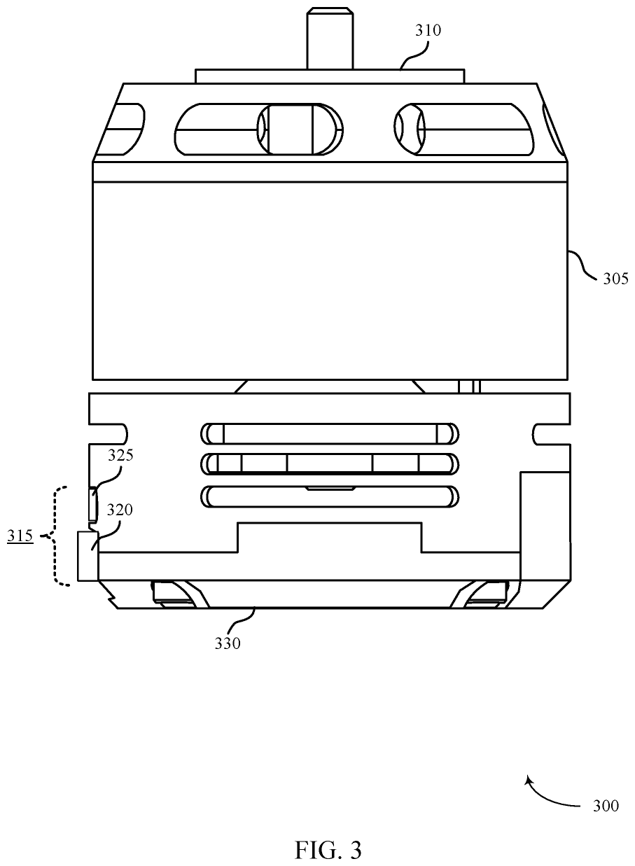

Housing 205 may be an example of, or include aspects of, the corresponding elements described with reference to FIGS. 1, 3, and 4. Motor 210 may be an example of, or include aspects of, the corresponding elements described with reference to FIGS. 1, 3, 4, and 8. Opening 215 may be an example of, or include aspects of, the corresponding elements described with reference to FIG. 3.

Power input 220 and data input 225 may be examples of, or include aspects of, the corresponding elements described with reference to FIGS. 1, 3-5, and 8. Base plate 230 may be an example of, or include aspects of, the corresponding elements described with reference to FIGS. 1, 3, 4, 6, and 7.

FIG. 3 shows an example of a side view of a motor unit system 300 in accordance with aspects of the present disclosure. Motor unit system 300 may be an example of, or include aspects of, the corresponding elements described with reference to FIGS. 1, 2, 4, and 8. Motor unit system 300 may include housing 305, motor 310, opening 315, power input 320, data input 325, and base plate 330.

Housing 305 may be an example of, or include aspects of, the corresponding elements described with reference to FIGS. 1, 2, and 4. Motor 310 may be an example of, or include aspects of, the corresponding elements described with reference to FIGS. 1, 2, 4, and 8. Opening 315 may be an example of, or include aspects of, the corresponding elements described with reference to FIG. 2.

Power input and data input 325 may be examples of, or include aspects of, the corresponding elements described with reference to FIGS. 1, 2, 4, 5, and 8. Base plate 330 may be an example of, or include aspects of, the corresponding elements described with reference to FIGS. 1, 2, 4, 6, and 7.

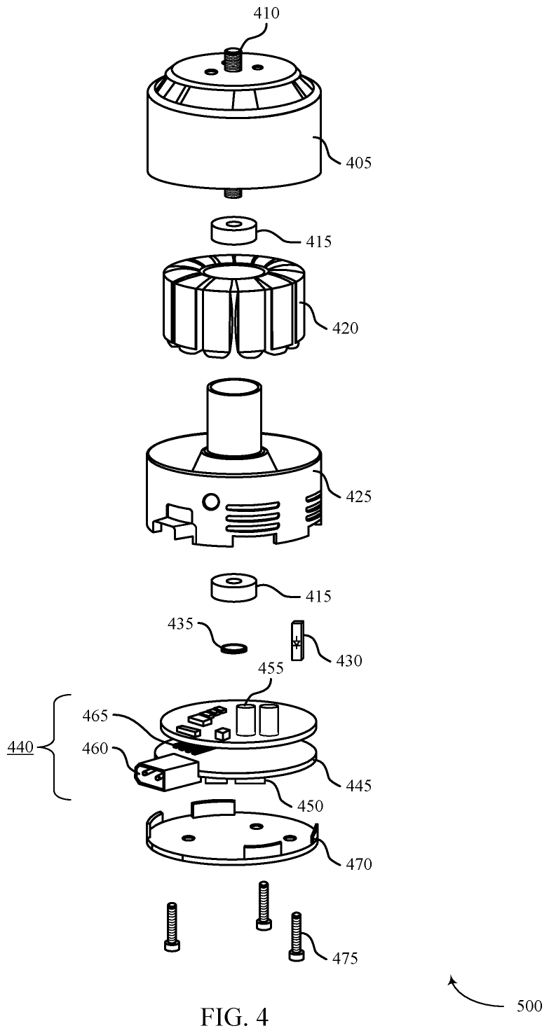

FIG. 4 shows an example of an exploded view of a motor unit system 400 in accordance with aspects of the present disclosure. Motor unit system 400 may be an example of, or include aspects of, the corresponding elements described with reference to FIGS. 1-3, and 8. Motor unit system 400 may include motor 405, shaft 410, ball bearing 415, winding 420, housing 425, light source 430, lock clip 435, motor controller 440, base plate 470, and fasteners 475.

Based on the configuration of the motor controller 440, air may be drawn over the printed circuit board 445 first (e.g., through the base plate 470), and then over the motor 405, so as to cool the motor controller 440 first, and the motor 405 second with the air, thereby preventing the heat transferred from the motor 405 to the air from being subsequently transferred to the motor controller 440.

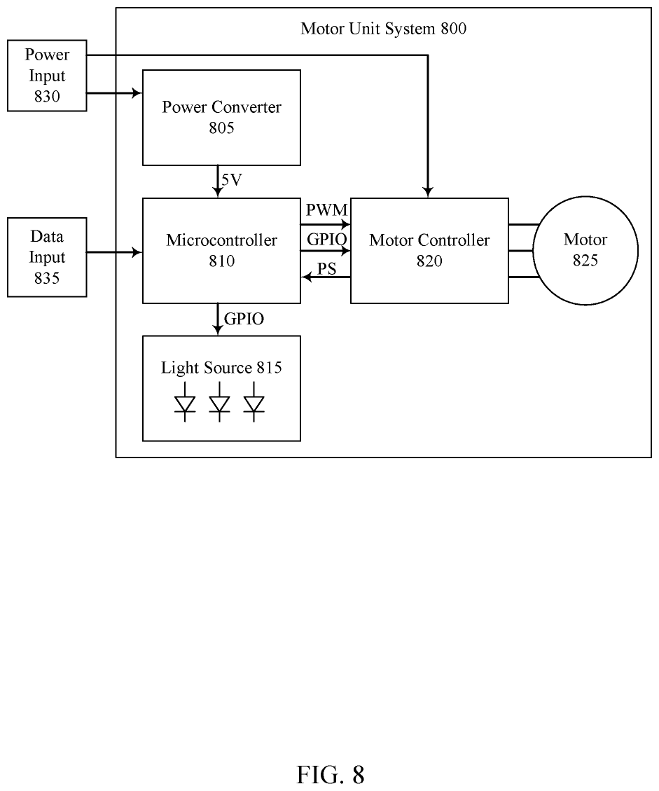

Motor 405 may be an example of, or include aspects of, the corresponding elements described with reference to FIGS. 1-3, and 8. Housing 425 may be an example of, or include aspects of, the corresponding elements described with reference to FIGS. 1-3. Light source 430 may be an example of, or include aspects of, the corresponding elements described with reference to FIG. 8.

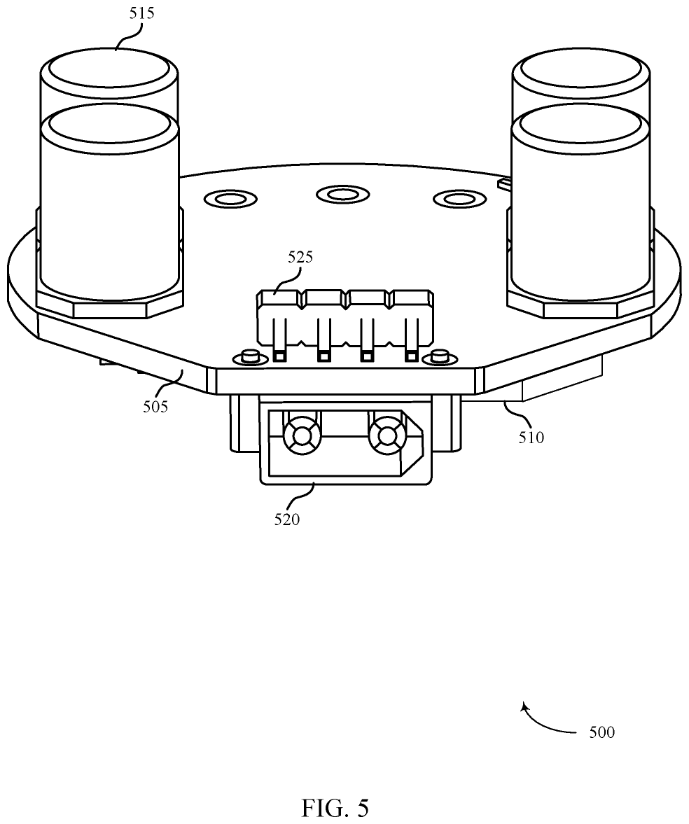

Motor controller 440 may be contained within the housing 425 and may include one or more printed circuit boards 445, and an integrated circuit 450 mounted on the bottom of one of the printed circuit boards 445. Motor controller 440 may be an example of, or include aspects of, the corresponding elements described with reference to FIGS. 5, 7, and 8. Motor controller 440 may include circuit board 445, integrated circuit 450, capacitors 455, power input 460, and data input 465.

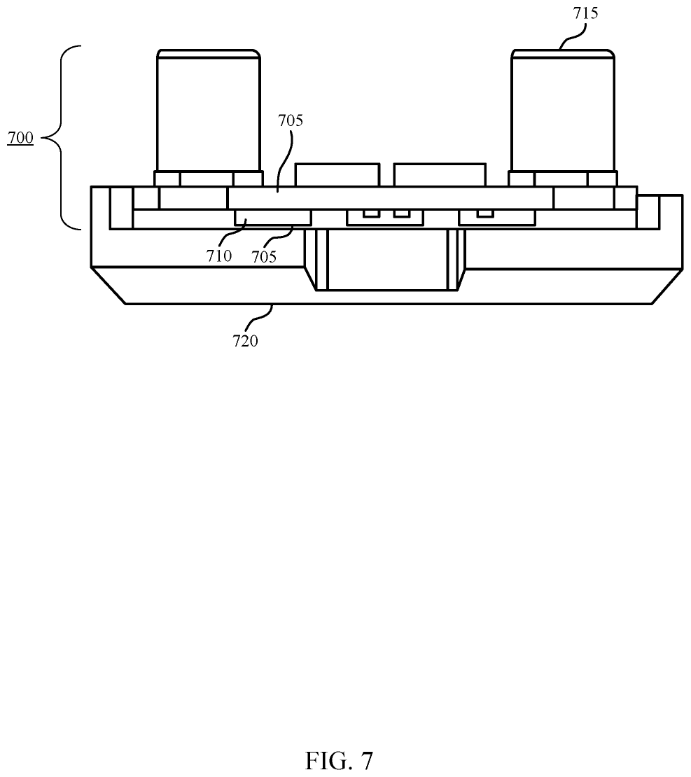

In some examples, a printed circuit board 445 includes an integrated circuit 450 mounted on the component side of the printed circuit board 445. Circuit boards 445 and integrated circuit 450 may be examples of, or include aspects of, the corresponding elements described with reference to FIGS. 5 and 7.

One or more capacitors 455 may also be mounted on the printed circuit board 445 on a backside of the printed circuit board 445, the backside being opposite the component side. Capacitor 455 may also be mounted on the printed circuit board 445 on the backside of the printed circuit board 445. Capacitors 455 may be an example of, or include aspects of, the corresponding elements described with reference to FIGS. 5 and 7.

Power input 460 and data input 465 may be an example of, or include aspects of, the corresponding elements described with reference to FIGS. 1-3, 5, and 8. Base plate 470 may be an example of, or include aspects of, the corresponding elements described with reference to FIGS. 1-3, 6, and 7.

FIG. 5 shows an example of a motor controller 500 in accordance with aspects of the present disclosure. Motor controller 500 may be an example of, or include aspects of, the corresponding elements described with reference to FIGS. 4, 7, and 8. Motor controller 500 may include circuit board 505, integrated circuit 510, capacitors 515, power input 520, and data input 525.

Circuit board 505, integrated circuit 510, and capacitors 515 may be examples of, or include aspects of, the corresponding elements described with reference to FIGS. 4 and 7. Power input 520 and data input 525 may be examples of, or include aspects of, the corresponding elements described with reference to FIGS. 1-4, and 8.

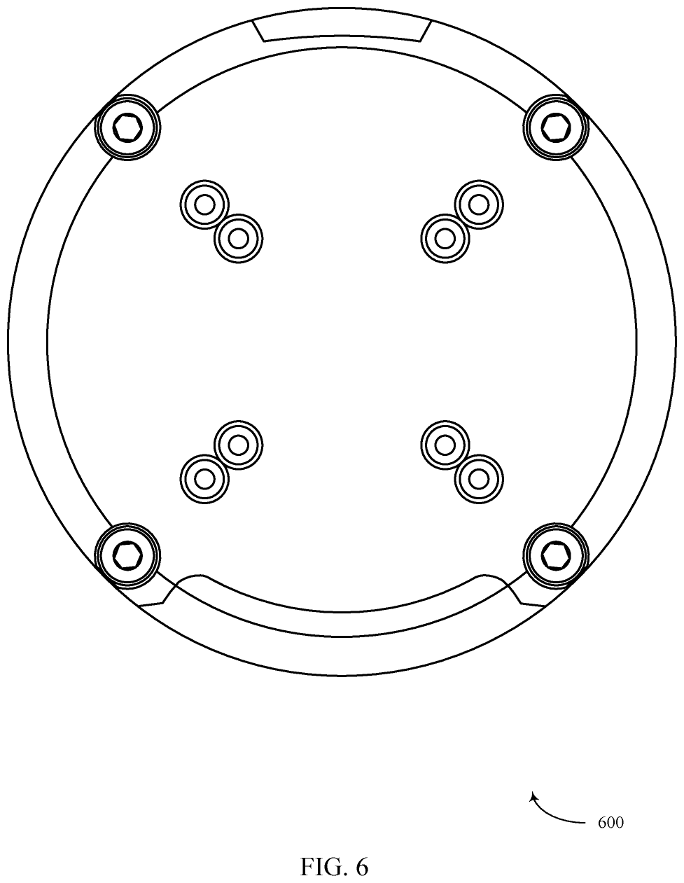

FIG. 6 shows an example of a base plate 600 in accordance with aspects of the present disclosure. Base plate 600 may be an example of, or include aspects of, the corresponding elements described with reference to FIGS. 1-4, and 7.

FIG. 7 shows an example of a motor controller 700 mounted to a base plate 720 in accordance with aspects of the present disclosure. The example shown includes motor controller 700, base plate 720, and thermal interface material 725.

Thermal interface material 725 may be interposed between the base plate 720 and the integrated circuit 710. The thermal interface material 725 may include thermal grease, thermal glue, thermal paste, thermal compound, thermal interface material 725, heat paste, heat gel, heat sink compound, etc.

Motor controller 700 may be an example of, or include aspects of, the corresponding elements described with reference to FIGS. 4, 5, and 8. Motor controller 700 may include circuit board 705, integrated circuit 710, and capacitor 715.

Circuit board 705, integrated circuit 710 and capacitors 715 may be an example of, or include aspects of, the corresponding elements described with reference to FIGS. 4 and 5. Base plate 720 may be an example of, or include aspects of, the corresponding elements described with reference to FIGS. 1-4, and 6.

FIG. 8 shows an example of a schematic of a motor unit system 800 in accordance with aspects of the present disclosure. The example shown includes motor unit system 800, power input 830, and data input 835.

Motor unit system 800 may be an example of, or include aspects of, the corresponding elements described with reference to FIGS. 1-4. Motor unit system 800 may include power converter 805, microcontroller 810, light source 815, motor controller 820, and motor 825.

Light source 815 may be an example of, or include aspects of, the corresponding elements described with reference to FIG. 4. Motor controller 820 may be an example of, or include aspects of, the corresponding elements described with reference to FIGS. 4, 5, and 7. Motor 825 may be an example of, or include aspects of, the corresponding elements described with reference to FIGS. 1-4.

Power input 830 and data input 835 may be an example of, or include aspects of, the corresponding elements described with reference to FIGS. 1-5.

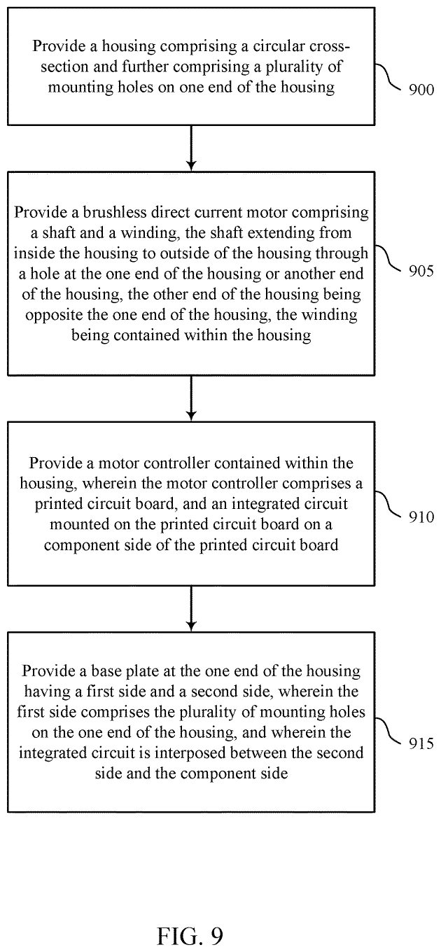

FIG. 9 shows an example of a process for manufacturing a motor unit system in accordance with aspects of the present disclosure. In some examples, these operations may be performed manually, or by a system including a processor executing a set of codes to control functional elements of a manufacturing apparatus. Additionally or alternatively, the processes may be performed manually, or using special-purpose hardware. Generally, these operations may be performed according to the methods and processes described in accordance with aspects of the present disclosure. For example, the operations may be composed of various substeps, or may be performed in conjunction with other operations described herein.

At step 900, a manufacturing apparatus may provide a housing including a circular cross-section and further including a plurality of mounting holes on one end of the housing. In some cases, the operations of this step may refer to a housing as described with reference to FIGS. 1-4.

At step 905, a manufacturing apparatus may provide a brushless direct current motor including a shaft and a winding, the shaft extending from inside the housing to outside of the housing through a hole at the one end of the housing or another end of the housing, the other end of the housing being opposite the one end of the housing, the winding being contained within the housing. In some cases, the operations of this step may refer to a motor as described with reference to FIGS. 1-4, and 8.

At step 910, a manufacturing apparatus may provide a motor controller contained within the housing, where the motor controller includes a printed circuit board, and an integrated circuit mounted on the printed circuit board on a component side of the printed circuit board. In some cases, the operations of this step may refer to a motor controller as described with reference to FIGS. 4, 5, 7, and 8.

At step 915, a manufacturing apparatus may provide a base plate at the one end of the housing having a first side and a second side, where the first side includes the plurality of mounting holes on the one end of the housing, and where the integrated circuit is interposed between the second side and the component side. In some cases, the operations of this step may refer to a base plate as described with reference to FIGS. 1-4, 6, and 7.

While the invention herein disclosed has been described by means of specific embodiments, examples and applications thereof, numerous modifications and variations could be made thereto by those skilled in the art without departing from the scope of the invention set forth in the claims.

What is claimed is:

1. A motor unit system, comprising:
a housing comprising a circular cross-section and further comprising a plurality of mounting holes on one end of the housing;
a brushless direct current motor comprising a shaft and a winding, the shaft extending from inside the housing to outside of the housing through a hole at the one end of the housing or another end of the housing, the other end of the housing being opposite the one end of the housing, the winding being contained within the housing;
a motor controller contained within the housing, wherein the motor controller comprises a printed circuit board, and an integrated circuit mounted on the printed circuit board on a component side of the printed circuit board; and
a base plate at the one end of the housing having a first side and a second side, wherein the first side comprises the plurality of mounting holes on the one end of the housing, and wherein the integrated circuit is interposed between the second side and the component side.

2. The motor unit system of claim 1, the motor unit system further comprising:
a thermal interface material interposed between the base plate and the integrated circuit.

3. The motor unit system of claim 2, wherein:
said printed circuit board comprises another integrated circuit mounted on the printed circuit board on the component side of the printed circuit board.

4. The motor unit system of claim 2, the motor unit system further comprising:
a capacitor mounted on the printed circuit board on a backside of the printed circuit board, the backside being opposite the component side.

5. The motor unit system of claim 4, the motor unit system further comprising:
a second capacitor mounted on the printed circuit board on the backside of the printed circuit board.

6. The motor unit system of claim 4, wherein:
said housing comprises a first opening in which the capacitor is positioned, and a second opening in which the other capacitor is positioned.

7. The motor unit system of claim 2, wherein:
the motor is thermally coupled to the housing and the integrated circuit is thermally coupled to the base plate.

8. An unmanned vehicle comprising:
a frame, one or more propulsion units;
a battery unit; and
a motor unit system; the motor unit system further comprising:
a housing comprising a circular cross-section and further comprising a plurality of mounting holes on one end of the housing;
a brushless direct current motor comprising a shaft and a winding, the shaft extending from inside the housing to outside of the housing through a hole at the one end of the housing or another end of the housing, the other end of the housing being opposite the one end of the housing, the winding being contained within the housing;
a motor controller contained within the housing, wherein the motor controller comprises a printed circuit board, and an integrated circuit mounted on the printed circuit board on a component side of the printed circuit board; and
a base plate at the one end of the housing having a first side and a second side, wherein the first side comprises the plurality of mounting holes on the one end of the housing, and wherein the integrated circuit is interposed between the second side and the component side.

9. The unmanned vehicle of claim 8, the unmanned vehicle further comprising:
a thermal interface material interposed between the base plate and the integrated circuit.

10. The unmanned vehicle of claim 9, wherein:
said printed circuit board comprises another integrated circuit mounted on the printed circuit board on the component side of the printed circuit board.

11. The unmanned vehicle of claim 9, the unmanned vehicle further comprising:
a capacitor mounted on the printed circuit board on a backside of the printed circuit board, the backside being opposite the component side.

12. The unmanned vehicle of claim 11, the unmanned vehicle further comprising:
a second capacitor mounted on the printed circuit board on the backside of the printed circuit board.

13. The unmanned vehicle of claim 11, wherein:
said housing comprises a first opening in which the capacitor is positioned, and a second opening in which the other capacitor is positioned.

14. The unmanned vehicle of claim 9, wherein:
the motor is thermally coupled to the housing and the integrated circuit is thermally coupled to the base plate.

15. A method of manufacturing a motor unit system, the method comprising:
providing a housing comprising a circular cross-section and further comprising a plurality of mounting holes on one end of the housing;
providing a brushless direct current motor comprising a shaft and a winding, the shaft extending from inside the housing to outside of the housing through a hole at the one end of the housing or another end of the housing, the other end of the housing being opposite the one end of the housing, the winding being contained within the housing;
providing a motor controller contained within the housing, wherein the motor controller comprises a printed circuit board, and an integrated circuit mounted on the printed circuit board on a component side of the printed circuit board; and
providing a base plate at the one end of the housing having a first side and a second side, wherein the first side comprises the plurality of mounting holes on the one end of the housing, and wherein the integrated circuit is interposed between the second side and the component side.

16. The method of claim 15, the method further comprising:
providing a thermal interface material interposed between the base plate and the integrated circuit.

17. The method of claim 16, wherein:
said printed circuit board comprises another integrated circuit mounted on the printed circuit board on the component side of the printed circuit board.

18. The method of claim 16, the method further comprising:
providing a capacitor mounted on the printed circuit board on a backside of the printed circuit board, the backside being opposite the component side.

19. The method of claim 18, the method further comprising:
providing a second capacitor mounted on the printed circuit board on the backside of the printed circuit board.

20. The method of claim 16, wherein:
the motor is thermally coupled to the housing and the integrated circuit is thermally coupled to the base plate.
